(19) United States
(12) Patent Application Publication
(10) Pub. No.: US 2023/0395768 A1
(43) Pub. Date: Dec. 7, 2023

(54) SEMICONDUCTOR LIGHT-EMITTING DEVICE AND DISPLAY APPARATUS COMPRISING SAME

(71) Applicant: LG ELECTRONICS INC., Seoul (KR)

(72) Inventor: Kyuhyun BANG, Seoul (KR)

(73) Assignee: LG ELECTRONICS INC., Seoul (KR)

(21) Appl. No.: 18/032,594

(22) PCT Filed: Oct. 22, 2020
(86) PCT No.: PCT/KR2020/014531

§ 371 Date: Apr. 19, 2023

(51) Int. Cl. H01L 33/62; H01L 25/075; H01L 25/16

(52) U.S. Cl. CPC H01L 33/62; H01L 25/0753; H01L 25/167

(57) ABSTRACT

A semiconductor light-emitting device and a display apparatus comprising same are disclosed. The semiconductor light-emitting device according to an embodiment of the present disclosure comprises: a first conductive type semiconductor layer and a second conductive type semiconductor layer; an active layer disposed between the first conductive type semiconductor layer and the second conductive type semiconductor layer; a metal-semiconductor (MS) contact layer formed on one surface of the second conductive type semiconductor layer, which is spaced apart from the active layer; and a first metal layer formed on the first conductive type semiconductor layer and a second metal layer formed to cover the MS contact layer, wherein the area over which one surface of the second conductive type semiconductor layer comes into contact with the MS contact layer is different from the area of the active layer.

### TECHNICAL FIELD

The present disclosure relates to a semiconductor light emitting device and a display device including the same.

### BACKGROUND ART

Recently, in a field of a display technology, display devices having excellent characteristics such as thinness, flexibility, and the like have been developed. On the other hand, currently commercialized major displays are represented by a LCD (liquid crystal display) and an AMOLED (Active Matrix Organic Light Emitting Diode).

On the other hand, LED (light emitting diode), which is a well-known semiconductor light-emitting device that converts electric current into light, has been used as a light source for a display image of an electronic device including an information and communication device along with a GaP:N-based green LED, starting with commercialization of a red LED using a GaAsP compound semiconductor in 1962. Accordingly, a method for solving the above-described problems by implementing a display using the semiconductor light-emitting device may be proposed.

The size of driving current for driving a semiconductor light emitting device is limited according to technological development and consumer demand for a large screen, low power, and high resolution. Assuming that the chip size of the semiconductor light emitting device is the same, the size of the driving current decreases, causing a problem with respect to luminous efficiency of the semiconductor light emitting device.

### DISCLOSURE

### Technical Problem

An object of embodiment(s) is to provide a semiconductor light emitting device and a display device including the same for resolving the problem of reducing the luminous efficiency of the semiconductor light emitting device, which is to be caused when the driving current is lowered.

### Technical Solution

According to an aspect, a semiconductor light emitting device may include a first conductive semiconductor layer and a second conductive semiconductor layer; an active layer disposed between the first conductive semiconductor layer and the second conductive semiconductor layer; a metal-semiconductor (MS) contact layer disposed on one surface of the second conductive semiconductor layer, which is spaced apart from the active layer; and a first metal layer disposed on the first conductive semiconductor layer and a second metal layer disposed by covering the MS contact layer, wherein a contact area between one surface of the second conductive semiconductor layer and the MS contact layer may be different from an area of the active layer.

An area of one surface of the second conductive semiconductor layer may be different from an area of another surface in contact with the active layer.

The second conductive semiconductor layer may be formed in a mesa structure.

An area of one surface of the second conductive semiconductor layer may correspond to an effective light emitting area.

Horizontal projection areas of the first metal layer and the second metal layer may be identical.

Cross-sectional areas of the first metal layer and the second metal layer may be identical.

The MS contact layer may be formed in ohmic contact.

According to another aspect, display device including a plurality of pixels connected to a data line and a scan line, respectively, each of the plurality of pixels may include a light emitter including at least one semiconductor light emitting device; and a driver supplying driving current to the semiconductor light emitting device, wherein an inverse relationship is not established between a size of the semiconductor light emitting device and current density of the drive current.

The semiconductor light emitting device may include a first conductive semiconductor layer and a second conductive semiconductor layer; an active layer disposed between the first conductive semiconductor layer and the second conductive semiconductor layer; an ohmic contact layer disposed on one surface of the second conductive semiconductor layer, which is spaced apart from the active layer; and a first metal layer disposed on the first conductive semiconductor layer and a second metal layer disposed by covering the ohmic contact layer, wherein a contact area between one surface of the second conductive semiconductor layer and the ohmic contact layer may be different from an area of the active layer.

The second conductive semiconductor layer may be formed in a mesa structure.

Current density of the driving current may be in inverse proportion to a contact area between the second conductive semiconductor layer and the ohmic contact layer.

Horizontal projection areas or cross-sectional areas of the first metal layer and the second metal layer may be identical.

The first conductive semiconductor layer may have a second region with a step difference in a first direction for a first region; the active layer may be formed in the second region; and the first region and the second region may have an identical area.

The first metal layer and the second metal layer may be disposed to face each other in a second direction.

Each of the plurality of pixels may further include a switching part connected to the data line and the scan line and differentiating activation of the driver.

### Advantageous Effects

According to a semiconductor light emitting device and a display device including the same according to the present disclosure, the current density of driving current may be increased regardless of a chip size of the semiconductor light emitting device, and thus the luminous efficiency of the semiconductor light emitting device, in particular, the external quantum efficiency may be improved.

According to the semiconductor light emitting device and the display device including the semiconductor light emitting device according to the present disclosure, linear luminance characteristics may be maintained when the display device expresses low gradation as the current density increases.

According to the semiconductor light emitting device and the display device including the same according to the present disclosure, while increasing the luminous efficiency in a state where the driving current is fixed, the semiconductor light emitting device may not have to reduce the chip size, thereby reducing the process difficulty and improving the product yield while reducing production costs.

### DESCRIPTION Of DRAWINGS

FIG. 1 is a conceptual diagram illustrating an embodiment of a display device using a semiconductor light emitting device according to the present disclosure.

FIG. 2 is a partially enlarged diagram showing a part A shown in FIG. 1, and FIGS. 3A and 3B are cross-sectional diagrams taken along the cutting lines B-B and C-C in FIG. 2.

FIG. 4 is a conceptual diagram illustrating the flip-chip type semiconductor light emitting device of FIG. 3.

FIGS. 5A to 5C are conceptual diagrams illustrating various examples of color implementation with respect to a flip-chip type semiconductor light emitting device.

FIG. 6 shows cross-sectional views of a method of fabricating a display device using a semiconductor light emitting device according to the present disclosure.

FIG. 7 is a perspective diagram of a display device using a semiconductor light emitting device according to another embodiment of the present disclosure.

FIG. 8 is a cross-sectional diagram taken along a cutting line D-D shown in FIG. 7.

FIG. 9 is a conceptual diagram showing a vertical type semiconductor light emitting device shown in FIG. 8.

FIG. 10 is a diagram conceptually showing a shape of a semiconductor light emitting device viewed from the front according to an embodiment of the present disclosure.

FIG. 11 conceptually shows a shape of a semiconductor light emitting device viewed from above according to an embodiment of the present disclosure.

FIG. 12 is a diagram conceptually showing a shape of a semiconductor light emitting device viewed from the front according to another embodiment of the present disclosure.

FIG. 13 is a diagram showing a second conductive semiconductor layer according to another embodiment of the present disclosure.

FIG. 14 is a graph showing a relationship between external quantum efficiency and current density according to driving current of a general semiconductor light emitting device.

FIG. 15 is a graph showing the relationship between external quantum efficiency and driving current according to a chip size of a general semiconductor light emitting device.

FIG. 16 is a diagram illustrating a display device according to an embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

In addition, when an element such as a layer, region or module is described as being “on” another element, it is to be understood that the element may be directly on the other element or there may be an intermediate element between them.

The display device described herein is a concept including a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like. However, it will be readily apparent to those skilled in the art that the configuration according to the embodiments described herein is applicable even to a new product that will be developed later as a display device.

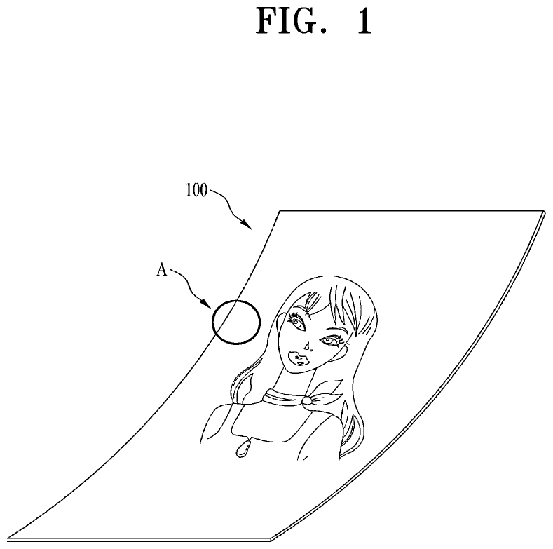

FIG. 1 is a conceptual view illustrating an embodiment of a display device using a semiconductor light emitting device according to the present disclosure.

According to the drawings, information processed by a controller (not shown) of a display device 100 may be displayed using a flexible display.

The flexible display may include, for example, a display that can be warped, bent, twisted, folded, or rolled by external force. For example, the flexible display may be, for example, a display manufactured on a thin and flexible substrate that can be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first sate is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of sub-pixels arranged in a matrix form. The unit pixel may mean, for example, a minimum unit for implementing one color.

The unit pixel of the flexible display may be implemented by a semiconductor light emitting device. In the present disclosure, a light emitting diode (LED) is exemplified as a type of the semiconductor light emitting device configured to convert electric current into light. The LED may be formed in a small size, and may thus serve as a unit pixel even in the second state.

Hereinafter, a flexible display implemented using the LED will be described in more detail with reference to the drawings.

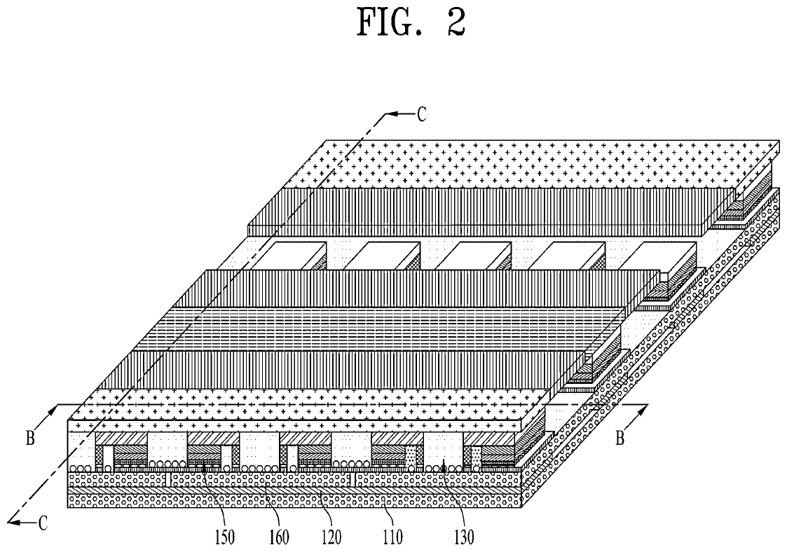

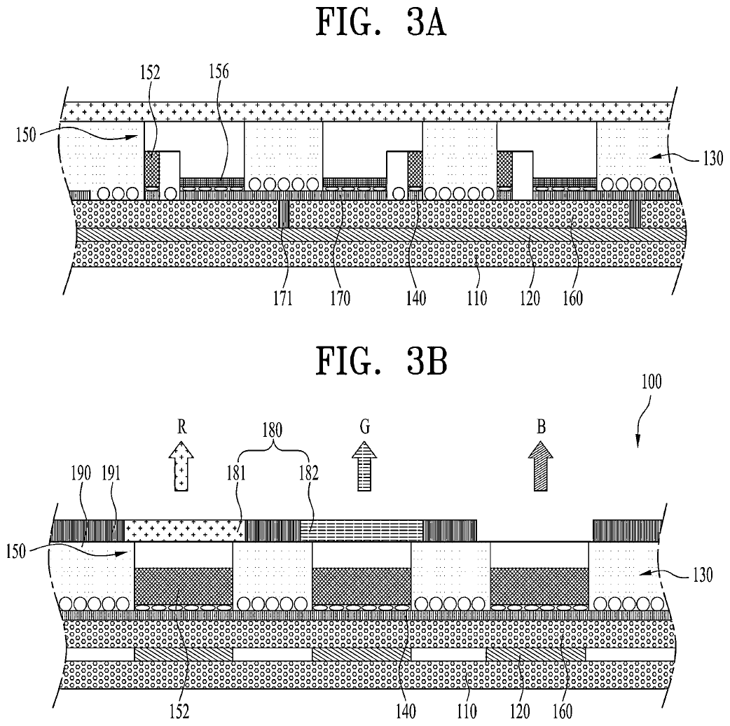

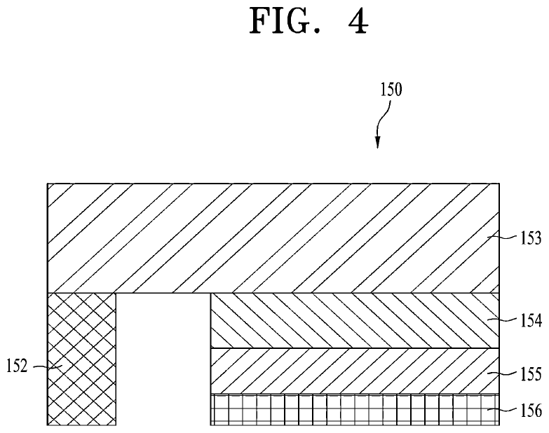

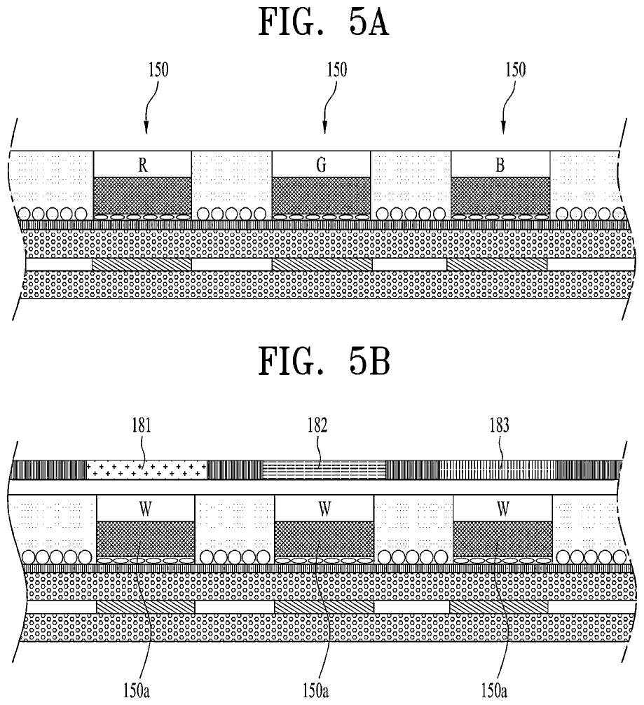

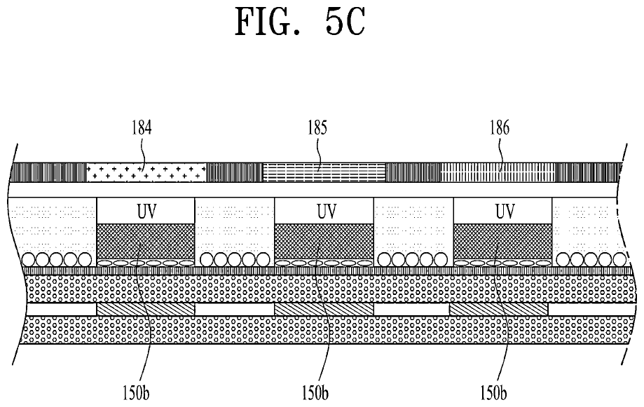

FIG. 2 is a partially enlarged view showing part A of FIG. 1, FIGS. 3A and 3B are cross-sectional views taken along lines B-B and C-C in FIG. 2, FIG. 4 is a conceptual view illustrating the flip-chip type semiconductor light emitting device of FIG. 3, and FIGS. 5A to 5C are conceptual views illustrating various examples of implementation of colors in relation to a flip-chip type semiconductor light emitting device.

As shown in FIGS. 2, 3A and 3B, the display device 100 using a passive matrix (PM) type semiconductor light emitting device is exemplified as the display device 100 using a semiconductor light emitting device. However, the examples described below are also applicable to an active matrix (AM) type semiconductor light emitting device.

The display device 100 may include a substrate 110, a first electrode 120, a conductive adhesive layer 130, a second electrode 140, and at least one semiconductor light emitting device 150.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

According to the drawings, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting device 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

According to the drawings, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

According to the drawings, the ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to the drawings, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting device 150 is connected thereto in a flip-chip form by applying heat and pressure. Thereby, the semiconductor light emitting device 150 is electrically connected to the first electrode 120 and the second electrode 140.

Referring to FIG. 4, the semiconductor light emitting device may be a flip chip-type light emitting device.

For example, the semiconductor light emitting device may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting devices 150. For example, p-type electrodes of semiconductor light emitting devices on left and right sides of an auxiliary electrode may be electrically connected to one auxiliary electrode.

More specifically, the semiconductor light emitting device 150 may be press-fitted into the conductive adhesive layer 130 by heat and pressure. Thereby, only the portions of the semiconductor light emitting device 150 between the p-type electrode 156 and the auxiliary electrode 170 and between the n-type electrode 152 and the second electrode 140 may exhibit conductivity, and the other portions of the semiconductor light emitting device 150 do not exhibit conductivity as they are not press-fitted. In this way, the conductive adhesive layer 130 interconnects and electrically connects the semiconductor light emitting device 150 and the auxiliary electrode 170 and interconnects and electrically connects the semiconductor light emitting device 150 and the second electrode 140.

The plurality of semiconductor light emitting devices 150 may constitute a light emitting device array, and a phosphor conversion layer 180 may be formed on the light emitting device array.

The light emitting device array may include a plurality of semiconductor light emitting devices having different luminance values. Each semiconductor light emitting device 150 may constitute a unit pixel and may be electrically connected to the first electrode 120. For example, a plurality of first electrodes 120 may be provided, and the semiconductor light emitting devices may be arranged in, for example, several columns. The semiconductor light emitting devices in each column may be electrically connected to any one of the plurality of first electrodes.

In addition, since the semiconductor light emitting devices are connected in a flip-chip form, semiconductor light emitting devices grown on a transparent dielectric substrate may be used. The semiconductor light emitting devices may be, for example, nitride semiconductor light emitting devices. Since the semiconductor light emitting device 150 has excellent luminance, it may constitute an individual unit pixel even when it has a small size.

According to the drawings, a partition wall 190 may be formed between the semiconductor light emitting devices 150. In this case, the partition wall 190 may serve to separate individual unit pixels from each other, and may be integrated with the conductive adhesive layer 130. For example, by inserting the semiconductor light emitting device 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting device 150. For example, the semiconductor light emitting device 150 may be a blue semiconductor light emitting device that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting device at a position of a unit pixel of red color, and the green phosphor 182 capable of converting blue light into green (G) light may be laminated on the blue semiconductor light emitting device at a position of a unit pixel of green color. Only the blue semiconductor light emitting device may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting device 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

Referring to FIG. 5A, each semiconductor light emitting device may be implemented as a high-power light emitting device emitting light of various colors including blue by using gallium nitride (GaN) as a main material and adding indium (In) and/or aluminum (Al).

In this case, each semiconductor light emitting device may be a red, green, or blue semiconductor light emitting device to form a unit pixel (sub-pixel). For example, red, green, and blue semiconductor light emitting devices R, G, and B may be alternately disposed, and unit pixels of red, green, and blue may constitute one pixel by the red, green and blue semiconductor light emitting devices. Thereby, a full-color display may be implemented.

Referring to FIG. 5B, the semiconductor light emitting device 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on a ultraviolet light emitting device. Not only visible light but also ultraviolet (UV) light may be used in the entire region of the semiconductor light emitting device. In an embodiment, UV may be used as an excitation source of the upper phosphor in the semiconductor light emitting device.

Referring back to this example, the semiconductor light emitting device is positioned on the conductive adhesive layer to constitute a unit pixel in the display device. Since the semiconductor light emitting device has excellent luminance, individual unit pixels may be configured despite even when the semiconductor light emitting device has a small size. Regarding the size of such an individual semiconductor light emitting device, the length of each side of the device may be, for example, 80 μm or less, and the device may have a rectangular or square shape. When the semiconductor light emitting device has a rectangular shape, the size thereof may be less than or equal to 20 μm×80 μm.

In addition, even when a square semiconductor light emitting device having a side length of 10 μm is used as a unit pixel, sufficient brightness to form a display device may be obtained. Therefore, for example, in case of a rectangular pixel having a unit pixel size of 600 μm×300 μm (i.e., one side by the other side), a distance of a semiconductor light emitting device becomes sufficiently long relatively. Thus, in this case, it is able to implement a flexible display device having high image quality over HD image quality.

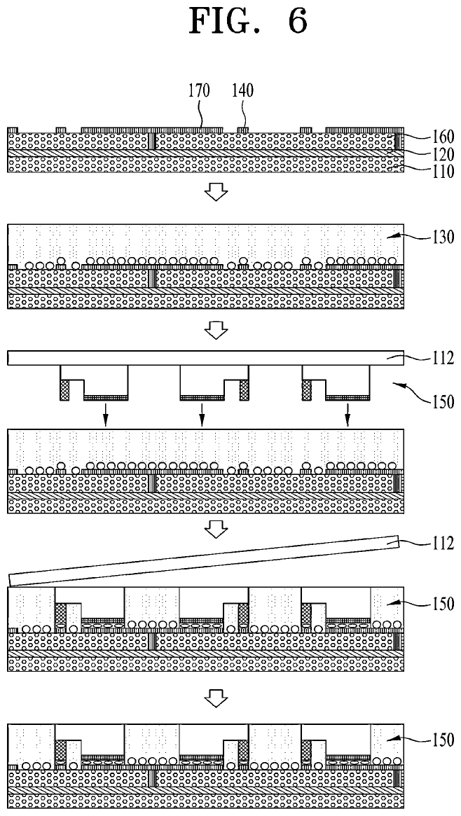

The above-described display device using the semiconductor light emitting device may be prepared by a new fabricating method. Such a fabricating method will be described with reference to FIG. 6 as follows.

FIG. 6 shows cross-sectional views of a method of fabricating a display device using a semiconductor light emitting device according to the present disclosure.

Referring to the drawing, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light emitting devices 150 configuring individual pixels are located to correspond to locations of the auxiliary electrode 170 and the second electrodes 140, is disposed in a manner that the semiconductor light emitting device 150 confronts the auxiliary electrode 170 and the second electrode 140.

In this regard, the temporary 112 substrate 112 is a growing substrate for growing the semiconductor light emitting device 150 and may include a sapphire or silicon substrate.

The semiconductor light emitting device is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light emitting device 150, the auxiliary electrode 170 and the second electrode 140 has conductivity, via which the electrodes and the semiconductor light emitting device 150 may be connected electrically. In this case, the semiconductor light emitting device 150 is inserted into the anisotropic conductive film, by which a partition may be formed between the semiconductor light emitting devices 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light emitting devices 150 exposed externally. If necessary, the wiring substrate 110 to which the semiconductor light emitting devices 150 are coupled may be coated with silicon oxide (SiOx) or the like to form a transparent insulating layer (not shown).

In addition, a step of forming a phosphor layer on one side of the semiconductor light emitting device 150 may be further included. For example, the semiconductor light emitting device 150 may include a blue semiconductor light emitting device emitting Blue (B) light, and a red or green phosphor for converting the blue (B) light into a color of a unit pixel may form a layer on one side of the blue semiconductor light emitting device.

The above-described fabricating method or structure of the display device using the semiconductor light emitting device may be modified into various forms. For example, the above-described display device may employ a vertical semiconductor light emitting device.

Furthermore, a modification or embodiment described in the following may use the same or similar reference numbers for the same or similar configurations of the former example and the former description may apply thereto.

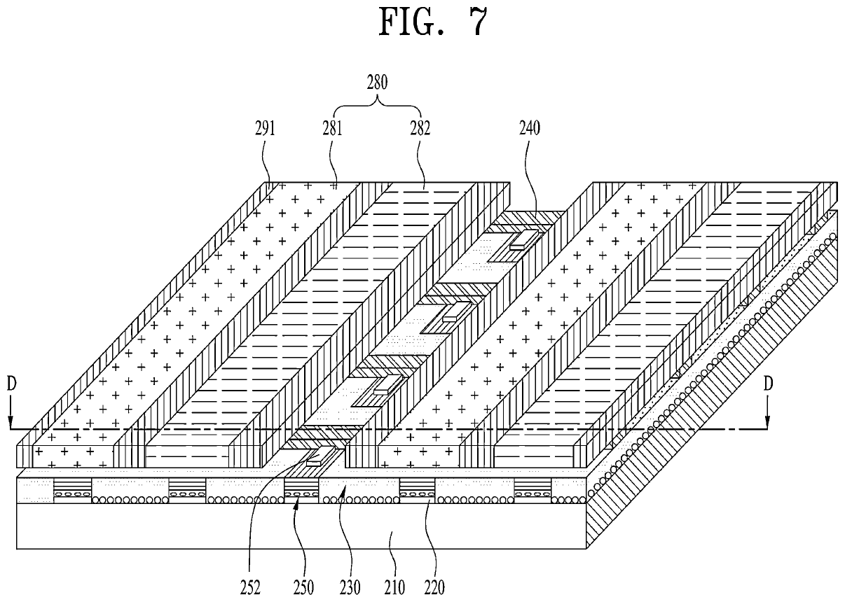

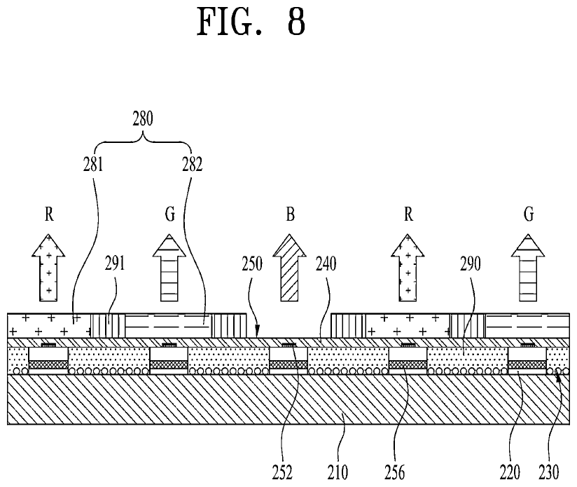

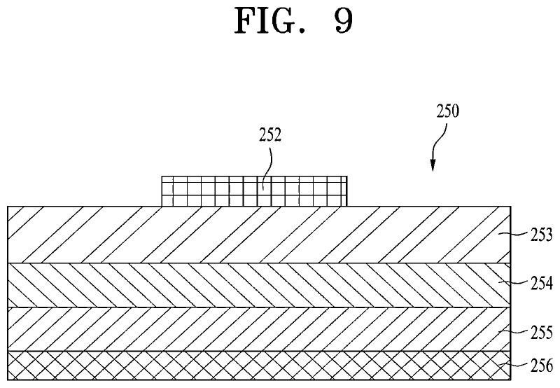

FIG. 7 is a perspective diagram of a display device using a semiconductor light emitting device according to another embodiment of the present disclosure, FIG. 8 is a cross-sectional diagram taken along a cutting line D-D shown in FIG. 8, and FIG. 9 is a conceptual diagram showing a vertical type semiconductor light emitting device shown in FIG. 8.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting device 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting device 250 is connected by applying heat and pressure thereto, the semiconductor light emitting device 250 is electrically connected to the first electrode 220. In doing so, the semiconductor light emitting device 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting device 250 and the first electrode 220 as well as mechanical connection.

Thus, the semiconductor light emitting device 250 is located on the conductive adhesive layer 230, via which an individual pixel is configured in the display device. As the semiconductor light emitting device 250 has excellent luminance, an individual unit pixel may be configured in small size as well. Regarding a size of the individual semiconductor light emitting device 250, a length of one side may be equal to or smaller than 80 μm for example and the individual semiconductor light emitting device 250 may include a rectangular or square device. For example, the rectangular device may have a size equal to or smaller than 20 μm×80 μm.

The semiconductor light emitting device 250 may have a vertical structure.

Among the vertical type semiconductor light emitting devices, a plurality of second electrodes 240 respectively and electrically connected to the vertical type semiconductor light emitting devices 250 are located in a manner of being disposed in a direction crossing with a length direction of the first electrode 220.

Referring to FIG. 9, the vertical type semiconductor light emitting device 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light emitting device 250 can dispose the electrodes at top and bottom, it is considerably advantageous in reducing a chip size.

Referring to FIG. 8 again, a phosphor layer 280 may formed on one side of the semiconductor light emitting device 250. For example, the semiconductor light emitting device 250 may include a blue semiconductor light emitting device 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting device. At a location of configuring a green unit pixel, the green phosphor 282 capable of converting blue light into green (G) light may be stacked on the blue semiconductor light emitting device. Moreover, the blue semiconductor light emitting device may be singly usable for a portion that configures a blue unit pixel. In this case, the unit pixels of red (R), green (G) and blue (B) may configure a single pixel.

Yet, the present disclosure is non-limited by the above description. In a display device to which a light emitting device of a flip chip type is applied, as described above, a different structure for implementing blue, red and green may be applicable.

Regarding the present embodiment again, the second electrode 240 is located between the semiconductor light emitting devices 250 and connected to the semiconductor light emitting devices electrically. For example, the semiconductor light emitting devices 250 are disposed in a plurality of columns, and the second electrode 240 may be located between the columns of the semiconductor light emitting devices 250.

Since a distance between the semiconductor light emitting devices 250 configuring the individual pixel is sufficiently long, the second electrode 240 may be located between the semiconductor light emitting devices 250.

The second electrode 240 may be formed as an electrode of a bar type that is long in one direction and disposed in a direction vertical to the first electrode.

In addition, the second electrode 240 and the semiconductor light emitting device 250 may be electrically connected to each other by a connecting electrode protruding from the second electrode 240. Particularly, the connecting electrode may include a n-type electrode of the semiconductor light emitting device 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting device 250 may be electrically connected to each other.

According to the drawings, the second electrode 240 may be located on the conductive adhesive layer 230. In some cases, a transparent insulating layer (not shown) containing silicon oxide (SiOx) and the like may be formed on the substrate 210 having the semiconductor light emitting device 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting device 250, there is a problem that ITO substance has poor adhesiveness to an n-type semiconductor layer. Therefore, according to the present disclosure, as the second electrode 240 is placed between the semiconductor light emitting devices 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

According to the drawings, a partition 290 may be located between the semiconductor light emitting devices 250. Namely, in order to isolate the semiconductor light emitting device 250 configuring the individual pixel, the partition 290 may be disposed between the vertical type semiconductor light emitting devices 250. In this case, the partition 290 may play a role in separating the individual unit pixels from each other and be formed with the conductive adhesive layer 230 as an integral part. For example, by inserting the semiconductor light emitting device 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 190. The partition 290 may include a black or white insulator depending on the purpose of the display device.

In case that the second electrode 240 is located right onto the conductive adhesive layer 230 between the semiconductor light emitting devices 250, the partition 290 may be located between the vertical type semiconductor light emitting device 250 and the second electrode 240 each. Therefore, an individual unit pixel may be configured using the semiconductor light emitting device 250. Since a distance between the semiconductor light emitting devices 250 is sufficiently long, the second electrode 240 can be placed between the semiconductor light emitting devices 250. And, it may bring an effect of implementing a flexible display device having HD image quality.

In addition, according to the drawings, a black matrix 291 may be disposed between the respective phosphors for the contrast ratio improvement. Namely, the black matrix 291 may improve the contrast between light and shade.

As described above, the semiconductor light emitting device 250 is positioned on the conductive adhesive layer 230, and constitutes a separate pixel in a display device therethrough. Since the semiconductor light emitting device 250 has excellent luminance, a separate unit pixel may be configured with a small size. Accordingly, a full color display in which unit pixels of red (R), green (G), and blue (B) form one pixel may be implemented by the semiconductor light emitting device.

The wiring substrate of the display device described above may be implemented differently depending on a driving method, that is, PM (Passive Matrix) driving or AM (Active Matrix) driving. For example, in the case of the AM driving method, the wiring substrate of the display device may be implemented as a backplane on which a thin film transistor (TFT) of amorphous silicon is formed. In this case, the amount of driving current applied to separate pixels may be limited according to a TFT channel size and wiring resistance. Even in a situation where the size of the driving current is limited, there is a high level of demand for the luminous efficiency of the semiconductor light emitting device in relation to power consumption and lifespan of the product.

Hereinafter, a method for improving luminous efficiency of a semiconductor light emitting device even under a condition in which driving current is limited will be described.

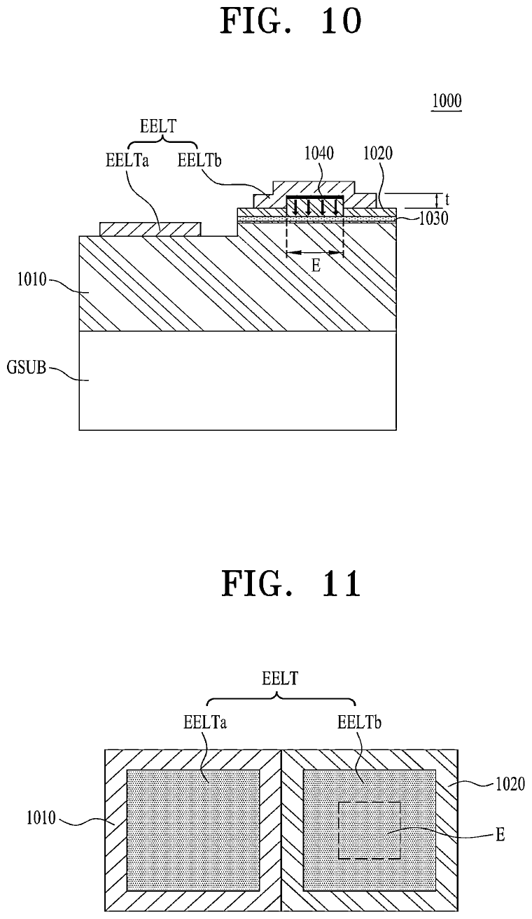

FIG. 10 is a diagram conceptually showing a shape of a semiconductor light emitting device viewed from the front according to an embodiment of the present disclosure, and FIG. 11 conceptually shows a shape of a semiconductor light emitting device viewed from above according to an embodiment of the present disclosure.

Referring to FIGS. 10 and 11, a semiconductor light emitting device 1000 according to an embodiment of the present disclosure includes a first conductive semiconductor layer 1010, a second conductive semiconductor layer 1020, an active layer 1030, and a Metal-Semiconductor (MS) contact layer 1040, and metal layers EELTa and EELTb.

The first conductive semiconductor layer 1010 and the second conductive semiconductor layer 1020 may be an n-type semiconductor layer and a p-type semiconductor layer, respectively. That is, the first conductive semiconductor layer 1010 and the second conductive semiconductor layer 1020 may be formed by doping a semiconductor crystal grown on a growth substrate GSUB with n-type and p-type impurities, respectively. The growth substrate GSUB may be a sapphire substrate, and the first conductive semiconductor layer 1010 and the second conductive semiconductor layer 1020 may be an n-type GaN layer and a p-type GaN layer, respectively.

Although not shown, a buffer layer may be formed between the growth substrate GSUB and the first conductive semiconductor layer 1010. The buffer layer is formed of GaN that is not doped with impurities, and may perform a function of protecting the active layer 1030 when the growth substrate GSUB is separated in a transfer process described later.

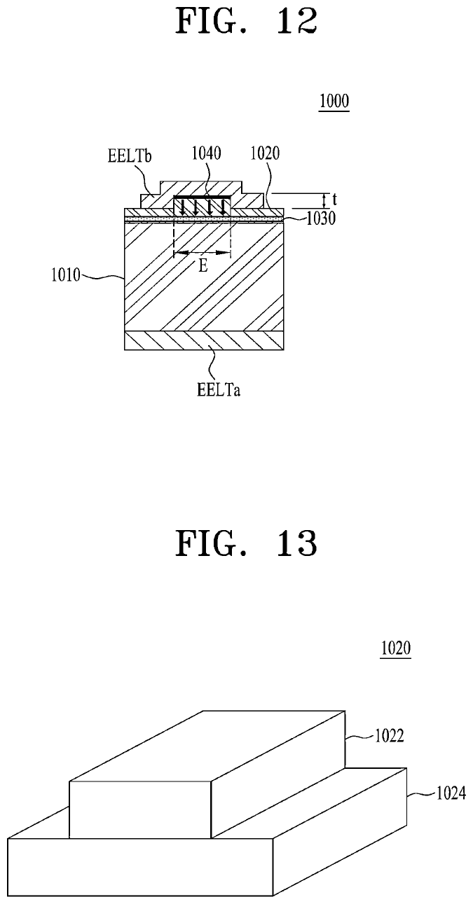

FIGS. 10 and 11 show an example in which the first conductive semiconductor layer 1010 and the second conductive semiconductor layer 1020 are formed like the flip chip type (horizontal type) semiconductor light emitting device of FIG. 4. However, the present disclosure is not limited thereto. As shown in FIG. 12 showing the semiconductor light emitting device 1000 according to another embodiment of the present disclosure, the semiconductor light emitting device 1000 is a vertical semiconductor light emitting device as shown in FIG. 9, and the first conductive layer semiconductor layer 1010 and the second conductive semiconductor layer 1020 may be formed as the n-type semiconductor layer 253 and the p-type semiconductor layer 255 of FIG. 9, respectively.

However, hereinafter, for convenience of description, unless otherwise specified, examples of the flip chip type will be mainly described, and this will be applied to a vertical semiconductor light emitting device as it is.

Referring continuously to FIGS. 10 and 11, one surface of the first conductive semiconductor layer 1010 may be divided into a first region and a second region having the same area. The first conductive semiconductor layer 1010 may be formed such that a first region and a second region have a step difference from each other. For example, the step difference may be about 0.5 μm to about 2 μm. For example, the step difference may be exposed by sequentially stacking the first conductive semiconductor layer 1010, the active layer 1030, and the second conductive semiconductor layer 1020 of the same area on the growth substrate GSUB and then etching and exposing a part of the first conductive semiconductor layer 1010 corresponding to the first region.

The active layer 1030, which is positioned between the first conductive semiconductor layer 1010 and the second conductive semiconductor layer 1020 and emits light, may be formed on a part of one surface of the first conductive semiconductor layer 1010, and for example, may be located in a second region formed higher by the step difference than the first region.

An area of one surface of the second conductive semiconductor layer 1020 may be different from an area of the other surface of the second conductive semiconductor layer 1020 in which the second conductive semiconductor layer 1020 contacts the active layer 1030. The other surface of the second conductive semiconductor layer 1020 may have the same area as or a similar area to that of the active layer 1030. For example, the second conductive semiconductor layer 1020 may be implemented in a mesa structure. In particular, as shown in FIG. 13, the second conductive semiconductor layer 1020 according to an embodiment of the present disclosure may include an upper part 1022 and a lower part 1024, and may be formed in a mesa structure in which the lower part 1024 has a larger cross-sectional area than the upper part 1022.

The area and height of the upper part 1022 (or the height of the lower part 1024) may be set in relation to sheet resistance in a lateral direction (horizontal direction) of the second conductive semiconductor layer 1020, which is applied when an effective light emitting area E described below is formed to correspond to an area of the upper part 1022. For example, as the area of the upper part 1022 narrows, the sheet resistance in the lateral direction of the second conductive semiconductor layer 1020 increases, and thus the effective light emitting area E may be formed with the same area as or similar to the area of the upper part 1022.

Such a mesa structure may be formed by forming the second conductive semiconductor layer 1020, forming a photoresistor having a smaller area than the other surface of the second conductive semiconductor layer 1020 on one surface of the second conductive semiconductor layer 1020, and then etching the same.

However, the present disclosure is not limited thereto. The second conductive semiconductor layer 1020 according to an embodiment of the present disclosure may be formed in various shapes in which a contact area of one surface of the second conductive semiconductor layer 1020 and the second conductive semiconductor layer 1040 is different from that of the active layer 1030. For example, the second conductive semiconductor layer 1020 may be formed in a truncated prism shape with a bottom surface wider than an upper surface.

Continuously, referring to FIGS. 10 and 11, the MS contact layer 1040 is formed on one surface of the second conductive semiconductor layer 1020. For example, when the second conductive semiconductor layer 1020 is formed of the mesa structure of FIG. 13, the MS contact layer 1040 may be formed on an upper surface of the upper part 1022 of the mesa structure. In this case, the contact area between one surface of the second conductive semiconductor layer 1020 and the MS contact layer 1040 is equal to the area of the upper surface of the upper part 1022 of the mesa structure and is different from the area of the active layer 1030.

The MS contact layer 1040 may be formed by adjusting a material contained in an adjacent semiconductor layer and a metal layer or may be formed by being stacked as separate layers. For example, when the second conductive semiconductor layer 1020 is a p-type semiconductor layer, the MS contact layer 1040 may be implemented by stacking ITO or an ohmic metal (e.g., Pt, Pd, or NiAu alloy) on the second conductive semiconductor layer 1020 to form ohmic contact.

The metal layers EELTa and EELTb include a first metal layer EELTa formed on the first conductive semiconductor layer 1010 and a second metal layer EELTb formed by covering the MS contact layer 1040. When the first conductive semiconductor layer 1010 is an n-type semiconductor layer and the first metal layer EELTa includes Ti, Cr, or the like, ohmic contact may be formed without an additional structure.

The second metal layer EELTb may cover the MS contact layer 1040 and may further be formed in a peripheral area of the MS contact layer 1040. For example, when the second conductive semiconductor layer 1020 is formed in a mesa structure as shown in FIG. 13, the second metal layer EELTb may be stacked by covering sidewalls of the MS contact layer 1040 and the upper part 1022, and a partial or entire part of an upper surface of the lower part 1024.

In this case, as shown in FIG. 11, areas of the first metal layer EELTa and the second metal layer EELTb when viewed from above, that is, horizontal projection areas may be the same. Alternatively, the entire cross-sectional area of the second metal layer EELTb having a mesa structure like the second conductive semiconductor layer 1020 may be the same as the cross-sectional area of the first metal layer EELTa. That is, in setting the current density of the driving current at which the luminous efficiency of the semiconductor light emitting device 1000 is to be optimized, the chip size may be maintained at a constant size, and thus the size of other components such as the metal layer may also be maintained at a constant size.

The semiconductor light emitting device 1000 according to an embodiment of the present disclosure may be implemented with the above structure, and under the condition that the driving current for the semiconductor light emitting device 1000 is limited, regardless of the chip size of the semiconductor light emitting device 1000, the luminous efficiency of the semiconductor light emitting device 1000 may be improved. For example, in a state where the magnitude of the driving current is the same, the chip size of the semiconductor light emitting device 1000 and the driving current for the semiconductor light emitting device 1000 are not in inverse proportion to each other. That is, while maintaining the chip size of the semiconductor light emitting device 1000, the current density of the driving current may be adjusted by adjusting the effective light emitting area E of the semiconductor light emitting device 1000, which will be explained in more detail.

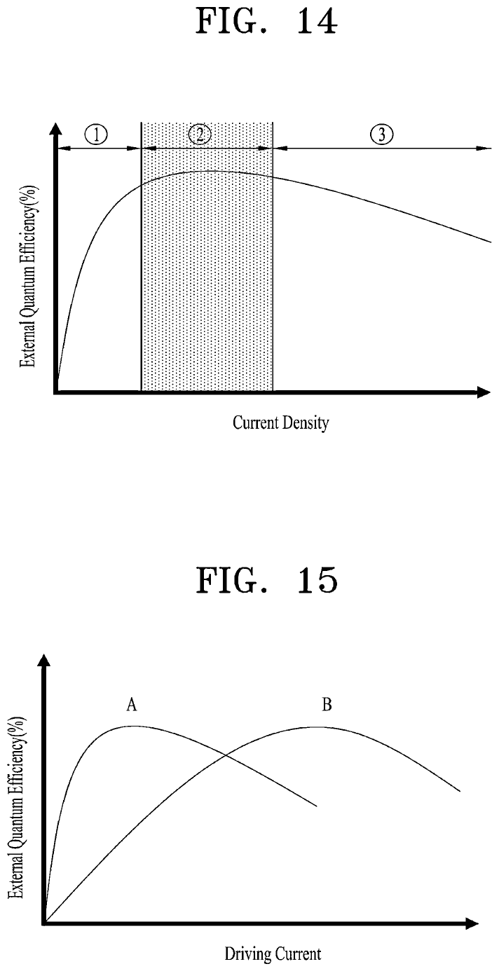

FIG. 14 is a graph showing a relationship between external quantum efficiency and current density according to driving current of a general semiconductor light emitting device.

Referring to FIG. 14, in a situation where the chip size of a general semiconductor light emitting device has a fixed value, the relationship between current density and external quantum efficiency according to the driving current supplied to the semiconductor light emitting device may be divided into three sections and expressed as follows.

During a first period ( [symbol] ), as the driving current supplied to the semiconductor light emitting device is applied, the current density of the driving current may increase, and the external quantum efficiency may also increase.

The external quantum efficiency of the active layer 1030 of FIG. 10 may correspond to a luminance value when the same energy is given. That is, when the external quantum efficiency is high, it means that the luminance value is high under the same energy, and therefore, the power consumption of the display device having the same may be reduced and the lifespan may be increased. For reference, the external quantum efficiency may vary depending on the substrate, electrode, and organic material of the semiconductor light emitting device, but only the relationship with the driving current is described here.

A peak value (maximum value) of the external quantum efficiency exists in the second interval ( [symbol] ). That is, even if the driving current increases, the external quantum efficiency starts to decrease at an arbitrary point during a second section [symbol] . After that, in a third section ( [symbol] ), even if the driving current increases, the external quantum efficiency decreases collectively. Therefore, in order to implement low power characteristics, the driving current needs to be set to a value corresponding to the second section ( [symbol] ).

However, the driving current value may be set to be located in the first section ( [symbol] ) by limiting the driving current described above, that is, by limiting the magnitude of the driving current to a very small value. Since the semiconductor light emitting device operates in the first section ( [symbol] ) instead of the second section ( [symbol] ), the luminous efficiency of the semiconductor light emitting device may be reduced. At this time, by reducing the chip size of the semiconductor light emitting device 1000, the semiconductor light emitting device may be controlled to operate in the second section ( [symbol] ) even if the size of the driving current is limited.

This is because the external quantum efficiency has a different value for the current density of the driving current depending on the chip size of the semiconductor light emitting device.

FIG. 15 is a graph showing the relationship between external quantum efficiency and driving current according to a chip size of a general semiconductor light emitting device.

Referring to FIGS. 14 and 15, when the chip size is small (A), a section in which the value of the external quantum efficiency becomes higher may occur below a specific current value than in the case when the chip size is large (B). Therefore, when the chip size of the semiconductor light emitting device is reduced, even if the size of the driving current is limited, the semiconductor light emitting device operates in the second period [symbol] , and the luminous efficiency thereof may be optimized.

However, the chip size of the semiconductor light emitting device 1000 increases the process difficulty in the above-described transfer process and may eventually cause a yield problem.

Since the semiconductor light emitting device 1000 according to an embodiment of the present disclosure has the above-described structure, luminous efficiency may be optimized while maintaining the chip size.

Referring back to FIG. 10, the effective light emitting area E may be set to correspond to a contact area between one side of the second conductive semiconductor layer 1020 and the MS contact layer 1040. When the second conductive semiconductor layer 1020 is formed in a mesa structure as shown in FIG. 13, an average thickness of the second conductive semiconductor layer 1020 may be reduced, thereby increasing sheet resistance of the second conductive semiconductor layer 1020 in the lateral direction (horizontal direction).

Therefore, since the driving current does not flow in the lateral direction of the second conductive semiconductor layer 1020, the effective light emitting area E is formed only as much as the area where the second conductive semiconductor layer 1020 and the MS contact layer 1040 come into contact. That is, the effective light emitting area E may correspond to an area where the second conductive semiconductor layer 1020 and the MS contact layer 1040 come into contact, that is, an area of an upper surface of the upper part 1022 in the mesa structure.

At this time, according to the sidewall height t of the lower part 1024 of the second conductive semiconductor layer 1020, the sheet resistance in the lateral direction of the second conductive semiconductor layer 1020 may be adjusted, and accordingly, the effective light emitting area E may be exactly formed with a required size.

Accordingly, it is possible to prevent a risk of reducing a process margin due to reduction of a chip size. That is, as described above, while maintaining the size of each component of the semiconductor light emitting device 1000, the driving current may be operated in the second section ( [symbol] ) on the graph of FIG. 14 despite the size limitation. For example, the semiconductor second metal layer EELTb may be formed to have the same or similar size as the first metal layer EELTa.

Therefore, the semiconductor light emitting device 1000 according to an embodiment of the present disclosure increases the luminous efficiency in a state where the driving current is fixed, but may not have to reduce the chip size of the semiconductor light emitting device to improve a product yield by reducing the process difficulty while reducing production costs.

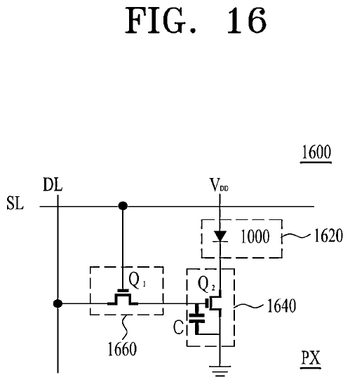

FIG. 16 is a diagram illustrating a display device according to an embodiment of the present disclosure.

Referring to FIG. 16, a display device 1600 according to an embodiment of the present disclosure includes a plurality of pixels PX connected to a data line DL and a scan line SL. Although FIG. 16 shows only one pixel PX for convenience, a plurality of pixels having the same structure may be formed in an array form.

When a data signal applied to the data line DL includes a plurality of color signals, the pixel PX may represent a color corresponding to one of the plurality of color signals. For example, when the display device 1600 according to an embodiment of the present disclosure displays an image with a color signal of red (R), green (G), and blue (B), a digital value of one point of an image displayed by three pixels PX representing one of R, G, and B may be determined.

The pixel PX includes a light emitter 1620 and a driver 1640.

The light emitter 1620 includes at least one of the semiconductor light emitting devices 1000 described above and emits light in a corresponding color. In this case, the semiconductor light emitting device 1000 itself may emit a corresponding color, or may indicate a corresponding color by a separate color filter included in the display device 1600.

One or more semiconductor light emitting devices 1000 may be provided for one pixel PX. For example, for one pixel PX, four the semiconductor light emitting devices 1000 may be provided. In this case, the four semiconductor light emitting devices 1000 may be positioned to be equally spaced apart from each other within the pixel PX.

The driver 1640 supplies driving current to the semiconductor light emitting device 1000. The driver 1640 may include a thin film transistor Q2 and a capacitor C. However, the present disclosure is not limited thereto and may be implemented in various forms corresponding to operating characteristics required for the display device 1600.

As described above, an increase in current density or an improvement in external quantum efficiency of the semiconductor light emitting device 1000 may be expected regardless of the chip size. That is, an inverse relationship between the size of the semiconductor light emitting device 1000 and the current density of the driving current is not established under the premise that the driving current is fixed in the display device 1600 according to the embodiment of the present disclosure. In the display device 1600 according to an embodiment of the present disclosure, the current density of the driving current is inversely proportional to the effective light emitting area E shown in FIG. 10.

Therefore, the display device 1600 according to the present disclosure may increase the current density of the driving current regardless of the chip size of the semiconductor light emitting device 1000, thereby improving the luminous efficiency of the semiconductor light emitting device 1000, particularly the external quantum efficiency. Thus, as the current density increases, the luminance characteristics of the display device may be maintained when expressing low gradations, and the chip size of the semiconductor light emitting device may not need to be reduced while increasing the luminous efficiency in the state in which the driving current is fixed, and the production cost may be reduced while improving the product yield by lowering the process difficulty.

Continuously, referring to FIG. 16, each pixel PX of the display device 1600 according to an embodiment of the present disclosure may be individually driven. To this end, each pixel PX may further include a switching part 1660. The switching part 1660 is turned on or off according to a data voltage applied to the data line DL and a scan voltage applied to the scan line SL.

The switching part 1660 may include a thin film transistor Q1 performing the on-off operation. FIG. 16 illustrates that the switching part 1660 includes only one thin film transistor Q1 for convenience of explanation, but is not limited thereto. The switching part 1660 corresponds to operating characteristics required of the display device 1600 and may include two or more thin film transistors, other devices other than the thin film transistors, or a parasitic capacitor.

Unlike FIG. 16, the display device 1600 may be implemented to be driven in a passive matrix mode.

The display device using the semiconductor light emitting device described above is not limited to the configuration and method of the embodiments described above, but the embodiments are configured by selectively combining all or part of each embodiment to make various modifications.

1. A semiconductor light emitting device comprising:
a first conductive semiconductor layer and a second conductive semiconductor layer;
an active layer disposed between the first conductive semiconductor layer and the second conductive semiconductor layer;
a metal-semiconductor (MS) contact layer disposed on one surface of the second conductive semiconductor layer, which is spaced apart from the active layer; and
a first metal layer disposed on the first conductive semiconductor layer and a second metal layer disposed by covering the MS contact layer,
wherein a contact area between one surface of the second conductive semiconductor layer and the MS contact layer is different from an area of the active layer.

2. The semiconductor light emitting device of claim 1, wherein an area of one surface of the second conductive semiconductor layer is different from an area of another surface in contact with the active layer.

3. The semiconductor light emitting device of claim 1, wherein the second conductive semiconductor layer is formed in a mesa structure.

4. The semiconductor light emitting device of claim 1, wherein an area of one surface of the second conductive semiconductor layer corresponds to an effective light emitting area.

5. The semiconductor light emitting device of claim 1, wherein horizontal projection areas of the first metal layer and the second metal layer are identical.

6. The semiconductor light emitting device of claim 1, wherein cross-sectional areas of the first metal layer and the second metal layer are identical.

7. The semiconductor light emitting device of claim 1, wherein the MS contact layer is formed in ohmic contact.

8. A display device including a plurality of pixels connected to a data line and a scan line, respectively, each of the plurality of pixels comprising:
a light emitter including at least one semiconductor light emitting device; and
a driver supplying driving current to the semiconductor light emitting device,
wherein an inverse relationship is not established between a size of the semiconductor light emitting device and current density of the drive current.

9. The display device of claim 8, wherein the semiconductor light emitting device includes:
a first conductive semiconductor layer and a second conductive semiconductor layer;
an active layer disposed between the first conductive semiconductor layer and the second conductive semiconductor layer;
an ohmic contact layer disposed on one surface of the second conductive semiconductor layer, which is spaced apart from the active layer; and
a first metal layer disposed on the first conductive semiconductor layer and a second metal layer disposed by covering the ohmic contact layer,
wherein a contact area between one surface of the second conductive semiconductor layer and the ohmic contact layer are different from an area of the active layer.

10. The display device of claim 9, wherein the second conductive semiconductor layer is formed in a mesa structure.

11. The display device of claim 9, wherein current density of the driving current is in inverse proportion to a contact area between the second conductive semiconductor layer and the ohmic contact layer.

12. The display device of claim 9, wherein horizontal projection areas or cross-sectional areas of the first metal layer and the second metal layer are identical.

13. The display device of claim 9, wherein:
the first conductive semiconductor layer has a second region with a step difference in a first direction for a first region;
the active layer is formed in the second region; and
the first region and the second region have an identical area.

14. The display device of claim 9, wherein the first metal layer and the second metal layer are disposed to face each other in a second direction.

15. The display device of claim 8, wherein each of the plurality of pixels further includes a switching part connected to the data line and the scan line and differentiating activation of the driver.

16. A semiconductor light emitting device comprising:
a first conductive semiconductor layer and a second conductive semiconductor layer;
an active layer disposed between the first conductive semiconductor layer and the second conductive semiconductor layer;
a metal-semiconductor (MS) contact layer disposed on one surface of the second conductive semiconductor layer, which is spaced apart from the active layer; and
a first metal layer disposed on the first conductive semiconductor layer and a second metal layer disposed by covering the MS contact layer,
wherein the second conductive semiconductor layer includes an upper part and a lower part having a larger cross-sectional area than the upper part.

17. The semiconductor light emitting device of claim 16, wherein the second conductive semiconductor layer is formed in a mesa structure.

18. The semiconductor light emitting device of claim 16, wherein an area of one surface of the second conductive semiconductor layer corresponds to an effective light emitting area.

19. The semiconductor light emitting device of claim 16, wherein horizontal projection areas of the first metal layer and the second metal layer are identical.

20. The semiconductor light emitting device of claim 16, wherein:
the first conductive semiconductor layer has a second region with a step difference in a first direction for a first region;
the active layer is formed in the second region; and
the first region and the second region have an identical area.
